(19) United States
(12) Patent Application Publication
(10) Pub. No.: US 2013/0135840 A1
(43) Pub. Date: May 30, 2013

(54) CONTAINER DATA CENTER

(71) Applicants: YAO-TING CHANG, Tu-Cheng (TW); HUNG-CHOU CHAN, Tu-Cheng (TW)

(72) Inventors: YAO-TING CHANG, Tu-Cheng (TW); HUNG-CHOU CHAN, Tu-Cheng (TW)

(73) Assignee: HON HAI PRECISION INDUSTRY CO., LTD., Tu-Cheng (TW)

(21) Appl. No.: 13/329,233

(22) Filed: Dec. 17, 2011

(30) Foreign Application Priority Data
Nov. 29, 2011 (TW) 100143825

(51) Int. Cl. H05K 9/00

(52) U.S. Cl. 361/816

(57) ABSTRACT

A container data center includes a container, a shield, a screen, and a hollow fixing frame. The container includes a sidewall defining a vent. The shield and the fixing frame are selectively mounted to the sidewall of the container such that the vent is covered by the shield or the screen sandwiched between the sidewall and the fixing frame.

### BACKGROUND

1. Technical Field

The present disclosure relates to a container data center.

2. Description of Related Art

Container data centers are centralized computing facilities, and include a container, and a number of information processing devices installed in the container. During operation, the information processing devices generate a lot of heat in the container, and a common method for dissipating the heat involves using air conditioners, and mounting a number of fans in the container. However, it is very expensive to purchase and operate the air conditioners and a large number of fans. Therefore an economic, energy-saving heat dissipation system for container data centers is desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is a partially exploded, isometric view of an exemplary embodiment of a container data center in a first using state.

FIG. 2 is a partially exploded, isometric view of an exemplary embodiment of the container data center in a second using state.

FIG. 3 is an assembled, isometric view of the container data center in the second using state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

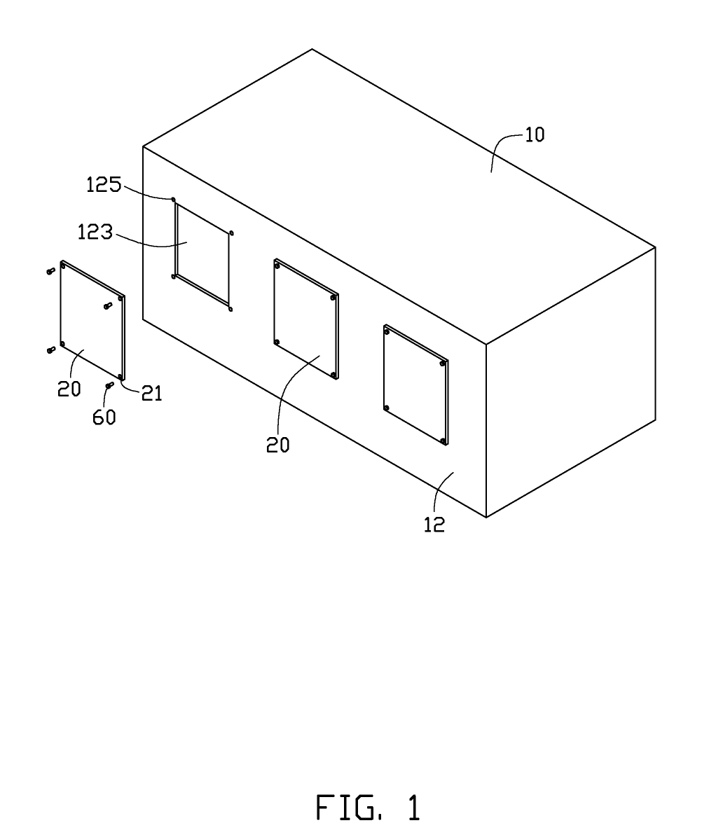

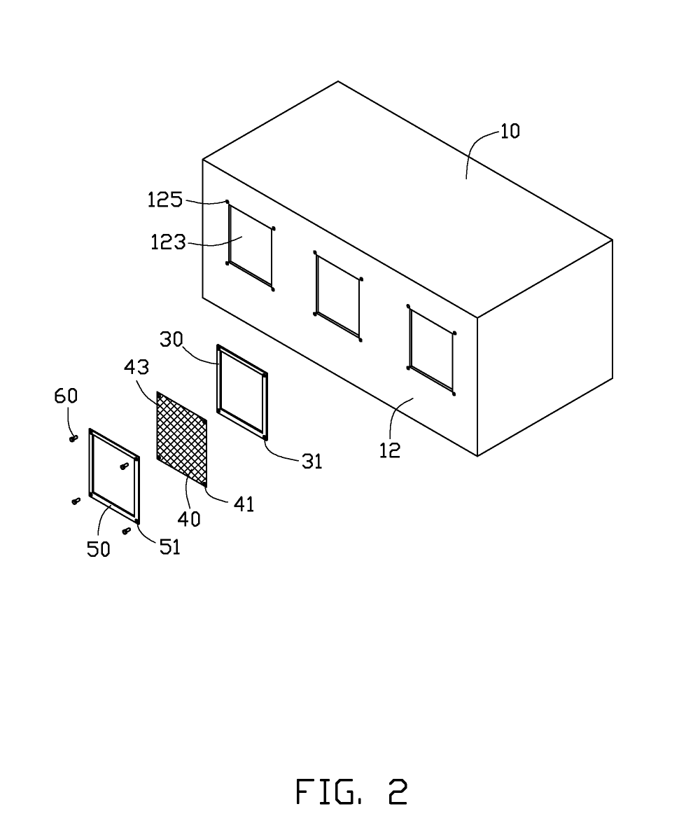

FIGS. 1 to 3, show an exemplary embodiment of a container data center including a metal container 10, a plurality of shields 20, a plurality of hollow rubber frames 30, a plurality of dust screens 40, a plurality of hollow fixing frames 50, and a plurality of fasteners 60. In the embodiment, the fasteners 60 are screws.

The container 10 includes a sidewall 12. A plurality of rectangular vents 123 is defined in the sidewall 12. Four fixing holes 125 are defined in the sidewall 12, respectively adjacent to four corners of each vent 123.

Each shield 20 is rectangular, and defines four through holes 21 respectively adjacent to four corners of the shield 20.

Each rubber frame 30 is rectangular, and defines four through holes 31 respectively adjacent to four corners of the rubber frame 30.

Each screen 40 is rectangular, and defines a plurality of holes 43. Four through holes 41 is defined in the screen 40, respectively adjacent to four corners of the screen 40.

Each fixing frame 50 is rectangular, and defines four through holes 51 respectively adjacent to four corners of the fixing frame 50.

In use, the shields 20 and the screens 40 can be selectively mounted to the sidewall 12 of the container 10.

When the surrounding environment of the container 10 is clean, meaning little or no dust in the air, the vents 123 of the container 10 can be kept open without installation of the shields 20 and the screens 40. At this time, airflow through the vents 123 is at a maximum, cooling air from outside can circulate through the container 10 minimizing use of air conditioners (not shown) in the container 10, thus saving power.

Referring to FIG. 1, when the surrounding environment of the container 10 is very dusty, the fasteners 60 are respectively extended through the through holes 21 and engaged in the corresponding fixing holes 125, to cover the vents 123 with the shields 20. At this time, operators can increase the use of air conditioners in the container 10 to control temperatures in the container 10.

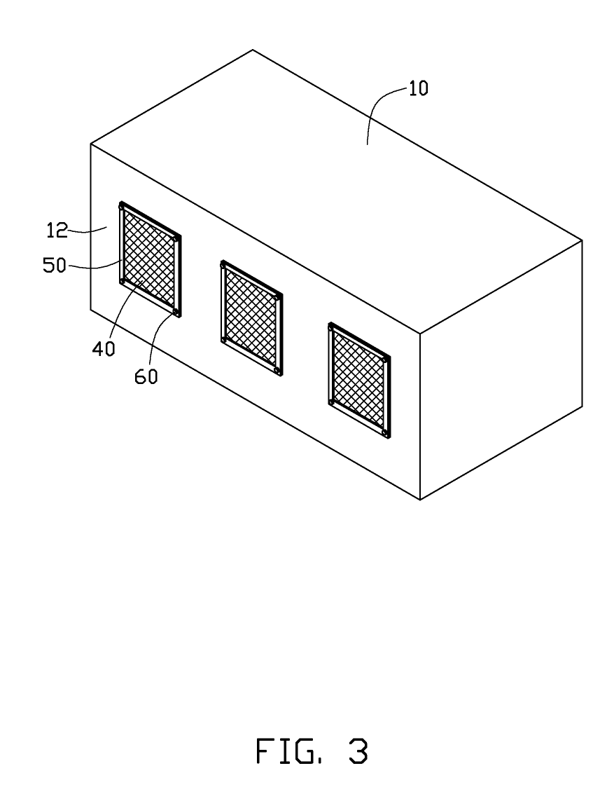

Referring to FIG. 3, when the surrounding environment of the container 10 is somewhat clean, meaning dust in the air is not excessive, the shields 20 can be detached from the sidewall 12, and the screens 40 can be installed over the vents 123 instead. To mount each screen 40, the fasteners 60 are extended through the through holes 51 and 41, and 31, and engaged in the corresponding fixing holes 125 around one of the vents 123. Thereby, the screen 40 is fixed to the sidewall 12 and covers one of the vents 123. The rubber frame 30 is sandwiched between the screen 40 and the sidewall 12 dust-proofing any clearance between the screen 40 and the sidewall 12. The other vents 123 can be respectively covered by the other screens 40. Although the screens 40 may impede airflow through the vents 123 somewhat, cooling air from outside can still be circulated through the container 10 and dependency on the air conditioners reduced.

In other embodiments, the fixing frames 50 are made of magnetic material. The rubber frames 30 and the fasteners 60 can be omitted. Each screen 40 can be sandwiched between a fixing frame 50 and the sidewall 12 by magnetic force of the corresponding fixing frame 50.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center, comprising:
a container comprising a sidewall defining a vent;
a shield;
a screen; and
a hollow fixing frame, wherein the shield and the fixing frame are selectively mounted to the sidewall of the container such that the vent is covered by the shield or the screen sandwiched between the sidewall and the fixing frame.

2. The container data center of claim 1, wherein edges of the screen are pasted to an inner side of the fixing frame facing the sidewall.

3. The container data center of claim 1, further comprising a hollow rubber frame sandwiched between the sidewall and the screen.

4. The container data center of claim 3, further comprising a plurality of fasteners, wherein the fasteners are extended through the fixing frame, the screen, and the rubber frame, and engaged in the sidewall, to fix the fixing frame, the screen, and the rubber frame to the sidewall.

5. The container data center of claim 1, further comprising a plurality of fasteners, wherein the shield is fixed to the sidewall by the fasteners.

6. The container data center of claim 1, wherein the container is made of metal, and the fixing frame is made of magnetic material, the screen is sandwiched between the fixing frame and the sidewall by magnetic force of the fixing frame.
